(19) United States
(12) Patent Application Publication
(10) Pub. No.: US 2024/0423080 A1
(43) Pub. Date: Dec. 19, 2024

(54) MANUFACTURING DEVICE OF DISPLAY DEVICE

(71) Applicant: Japan Display Inc., Tokyo (JP)

(72) Inventors: Yuki HAMADA, Tokyo (JP); Takanobu TAKENAKA, Tokyo (JP); Hirofumi MIZUKOSHI, Tokyo (JP); Masaru TAKAYAMA, Tokyo (JP)

(73) Assignee: Japan Display Inc., Tokyo (JP)

(21) Appl. No.: 18/740,567

(22) Filed: Jun. 12, 2024

(30) Foreign Application Priority Data
Jun. 16, 2023 (JP) 2023-099287

(51) Int. Cl. H10K 71/16

(52) U.S. Cl. CPC H10K 71/164

(57) ABSTRACT

According to one embodiment, a manufacturing device includes a main manufacturing line and a sub-line. The main manufacturing line includes a preprocessing portion, an in-line first evaporation device, a first CVD device for forming a first inorganic insulating layer of a sealing layer, a dry etching device for reducing a thickness of the first inorganic insulating layer, and a second CVD device for forming a second inorganic insulating layer of the sealing layer. The sub-line forms a detour which is different from the main manufacturing line as a conveyance path for conveying a processing substrate. The main manufacturing line and the sub-line form a loop conveyance path.

### CROSS-REFERENCE TO RELATED APPLICATION

This application is based upon and claims the benefit of priority from Japanese Patent Application No. 2023-099287, filed Jun. 16, 2023, the entire contents of which are incorporated herein by reference.

### FIELD

Embodiments described herein relate generally to a manufacturing device of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In manufacturing devices for manufacturing the display devices, the reduction in the manufacturing yield is required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a diagram for explaining the manufacturing method of the display device DSP.

FIG. 5 is a diagram for explaining the manufacturing method of the display device DSP.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram for explaining the manufacturing method of the display device DSP.

FIG. 11 is a diagram showing a configuration example of a display element 20.

FIG. 12 is a diagram showing a configuration example of a manufacturing device 100.

FIG. 13 is a diagram showing a configuration example of an evaporation device ID1.

FIG. 14 is a diagram showing another configuration example of the evaporation device ID1.

FIG. 15 is a diagram showing the outline of CVD devices and dry etching devices.

FIG. 16 is a diagram showing another configuration example of the manufacturing device 100.

### DETAILED DESCRIPTION

Embodiments described herein aim to provide a manufacturing device of a display device such that the reduction in the manufacturing yield can be prevented.

In general, according to one embodiment, a manufacturing device of a display device comprises a main manufacturing line which manufactures a display device while conveying a processing substrate in which a lower electrode is formed, and a sub-line connected to the main manufacturing line. The main manufacturing line comprises a preprocessing portion which performs preprocessing for the processing substrate, an in-line first evaporation device which is located on a downstream side in a conveyance direction of the processing substrate relative to the preprocessing portion and has a plurality of evaporation chambers for forming an organic layer, an upper electrode and a cap layer on the lower electrode in order, at least one first CVD device which is located on a downstream side of the first evaporation device and is provided for forming a first inorganic insulating layer of a sealing layer on the cap layer, at least one dry etching device which is located on a downstream side of the first CVD device and is provided for reducing a thickness of the first inorganic insulating layer, and at least one second CVD device which is located on a downstream side of the dry etching device and is provided for forming a second inorganic insulating layer of the sealing layer on the first inorganic insulating layer. The sub-line forms a detour which is different from the main manufacturing line as a conveyance path for conveying the processing substrate. The main manufacturing line and the sub-line form a loop conveyance path.

The embodiments can provide a manufacturing device of a display device such that the reduction in the manufacturing yield can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view. When terms indicating the positional relationships of two or more structural elements, such as “on”, “above”, “between” and “face”, are used, the target structural elements may be directly in contact with each other or may be spaced apart from each other as a gap or another structural element is interposed between them. The positive direction of the Z-axis is referred to as “on” or “above”.

The display device of the embodiment is an organic electroluminescent display device comprising an organic light emitting diode (OLED) as a display element, and could be mounted on a television, a personal computer, a vehicle-mounted device, a tablet, a smartphone, a mobile phone, etc.

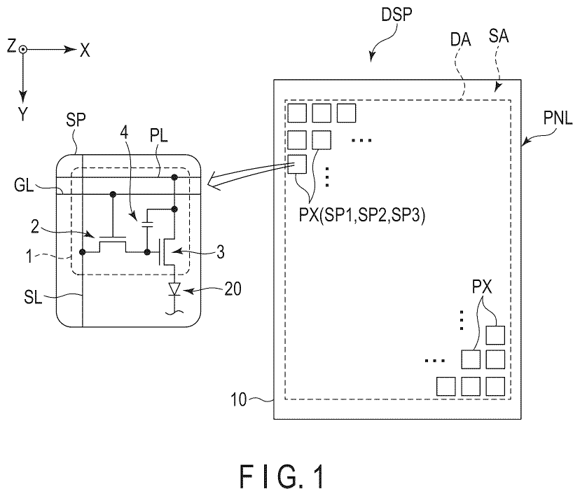

FIG. 1 is a diagram showing a configuration example of a display device DSP.

The display device DSP comprises a display panel PNL comprising a display area DA which displays an image and a surrounding area SA located on an external side relative to the display area DA on an insulating substrate 10. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors.

Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4 etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

Although not described in detail, a terminal for connecting an IC chip and a flexible printed circuit is provided in the surrounding area SA.

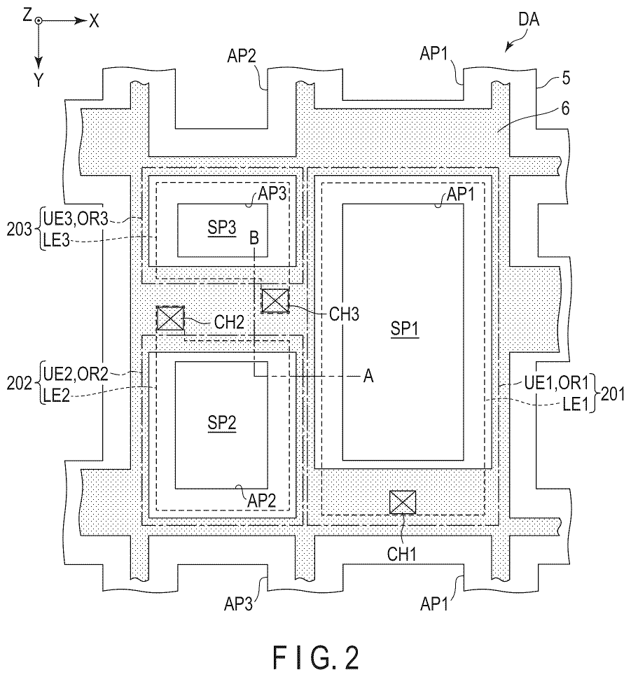

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 has apertures AP1, AP2 and AP3 in subpixels SP1, SP2 and SP3, respectively. The inorganic insulating layer 5 having these apertures AP1, AP2 and AP3 may be called a rib.

The partition 6 overlaps the inorganic insulating layer 5 as seen in plan view. The partition 6 is formed into a grating shape surrounding the apertures AP1, AP2 and AP3. In other words, the partition 6 has apertures in subpixels SP1, SP2 and SP3 in a manner similar to that of the inorganic insulating layer 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The peripheral portion of the lower electrode LE1 is covered with the inorganic insulating layer 5. The display element 201 comprising the lower electrode LE1, the organic layer OR1 and the upper electrode UE1 is surrounded by the partition 6 as seen in plan view. The peripheral portion of each of the organic layer OR1 and the upper electrode UE1 overlaps the inorganic insulating layer 5 as seen in plan view. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The peripheral portion of the lower electrode LE2 is covered with the inorganic insulating layer 5. The display element 202 comprising the lower electrode LE2, the organic layer OR2 and the upper electrode UE2 is surrounded by the partition 6 as seen in plan view. The peripheral portion of each of the organic layer OR2 and the upper electrode UE2 overlaps the inorganic insulating layer 5 as seen in plan view. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The peripheral portion of the lower electrode LE3 is covered with the inorganic insulating layer 5. The display element 203 comprising the lower electrode LE3, the organic layer OR3 and the upper electrode UE3 is surrounded by the partition 6 as seen in plan view. The peripheral portion of each of the organic layer OR3 and the upper electrode UE3 overlaps the inorganic insulating layer 5 as seen in plan view. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

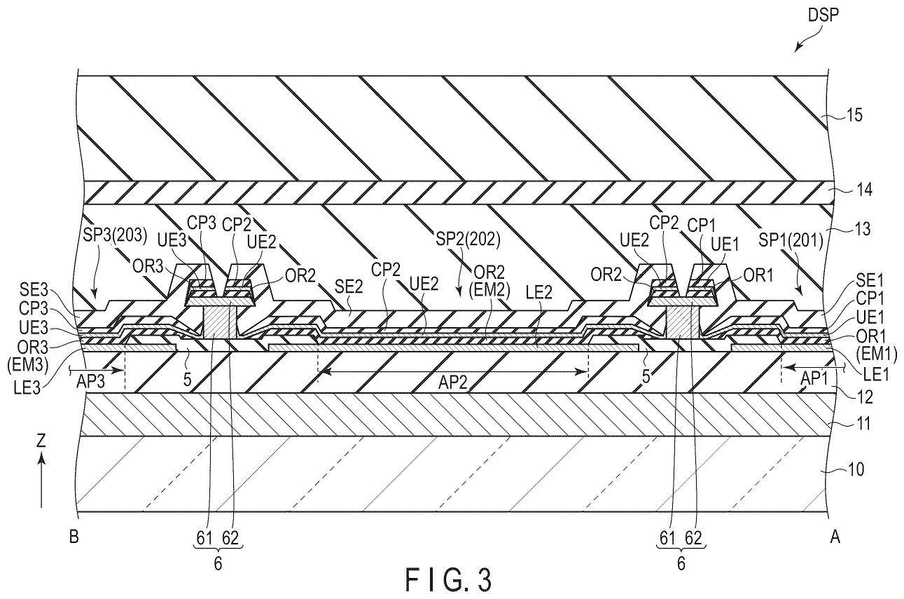

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The inorganic insulating layer 5 is provided on the insulating layer 12 and the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The insulating layer 12 is covered with the inorganic insulating layer 5 between, of the lower electrodes LE1, LE2 and LE3, the lower electrodes which are adjacent to each other. The lower electrodes LE1, LE2 and LE3 are connected to the pixel circuits 1 of subpixels SP1, SP2 and SP3, respectively, through the contact holes provided in the insulating layer 12. It should be noted that, although the contact holes of the insulating layer 12 are omitted in FIG. 3, the contact holes correspond to the contact holes CH1, CH2 and CH3 of FIG. 2.

The partition 6 includes a conductive lower portion (stem) 61 provided on the inorganic insulating layer 5 and an upper portion (shade) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. The both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

In the example of FIG. 3, subpixel SP1 comprises a cap layer CP1 and a sealing layer SE1. Subpixel SP2 comprises a cap layer CP2 and a sealing layer SE2. Subpixel SP3 comprises a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers each member of subpixel SP1.

The sealing layer SE2 is provided on the cap layer CP2, is in contact with the partition 6 and continuously covers each member of subpixel SP2.

The sealing layer SE3 is provided on the cap layer CP3, is in contact with the partition 6 and continuously covers each member of subpixel SP3.

In the example of FIG. 3, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element 203).

It could be that the organic layer OR1, the upper electrode UE1, the cap layer CP1, the organic layer OR2, the upper electrode UE2, the cap layer CP2, the organic layer OR3, the upper electrode UE3 or the cap layer CP3 is not present on the partition 6.

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. The resin layer 13 is covered with a sealing layer 14. The sealing layer 14 is covered with a resin layer 15.

Each of the inorganic insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. The upper portion 62 of the partition 6 is formed of, for example, a conductive material. However, the upper portion 62 may be formed of an insulating material. The lower portion 61 is formed of a material which is different from that of the upper portion 62.

For example, each of the lower electrodes LE1, LE2 and LE3 is a multilayer body including a transparent electrode formed of an oxide conductive material such as indium tin oxide (ITO) and a metal electrode formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other. It should be noted that at least one of the cap layers CP1, CP2 and CP3 may be omitted.

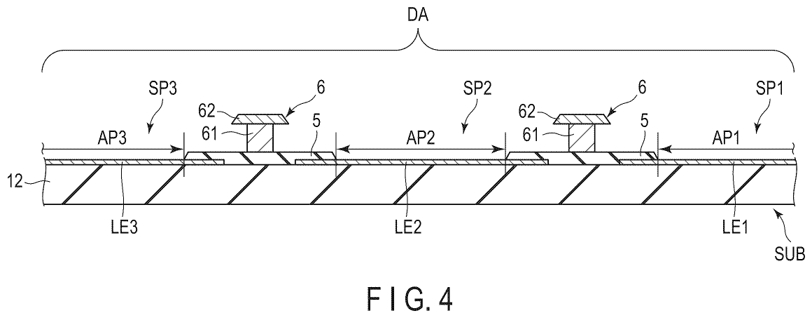

Now, this specification explains the manufacturing method of the display device DSP with reference to FIG. 4 to FIG. 10. In FIG. 4 to FIG. 10, the illustration of the lower side of the insulating layer 12 is omitted.

First, as shown in FIG. 4, a processing substrate SUB is prepared. The process of preparing the processing substrate SUB includes the process of forming the lower electrode LE1 of subpixel SP1, the lower electrode LE2 of subpixel SP2 and the lower electrode LE3 of subpixel SP3 on the insulating layer 12, the process of forming the inorganic insulating layer 5 having the apertures AP1, AP2 and AP3 overlapping the lower electrodes LE1, LE2 and LE3, respectively, and the process of forming the partition 6 including the lower portion 61 located on the inorganic insulating layer 5 and the upper portion 62 located on the lower portion 61 and protruding from the side surfaces of the lower portion 61. It should be noted that the partition 6 may be formed after the formation of the apertures AP1, AP2 and AP3 in the inorganic insulating layer 5. Alternatively, the apertures AP1, AP2 and AP3 may be formed after the formation of the partition 6.

Subsequently, the display element 201 is formed.

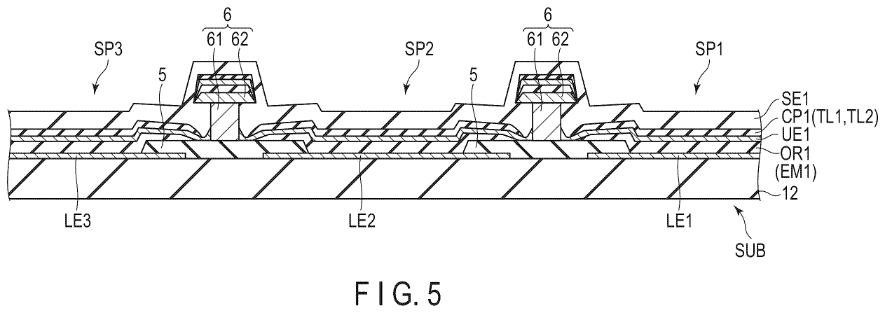

First, the processing substrate SUB is carried into an in-line evaporation device as described later. Subsequently, as shown in FIG. 5, the organic layer OR1 is formed by depositing the materials for forming the hole injection layer, the hole transport layer, the electron blocking layer, the light emitting layer (EM1), the hole blocking layer, the electron transport layer, the electron injection layer, etc., on the lower electrode LE1 in series using the partition 6 as a mask.

Subsequently, the upper electrode UE1 is formed by depositing a mixture of magnesium and silver on the organic layer OR1 using the partition 6 as a mask. The upper electrode UE1 covers the organic layer OR1 and is in contact with the lower portion 61.

Subsequently, the cap layer CP1 is formed by depositing a high-refractive material for forming a first transparent layer TL1 and a low-refractive material for forming a second transparent layer TL2 in series on the upper electrode UE1 using the partition 6 as a mask.

These organic layer OR1, upper electrode UE1 and cap layer CP1 are continuously formed while maintaining a vacuum environment.

Subsequently, the processing substrate SUB is carried into a chemical vapor deposition (CVD) device as described later. The sealing layer SE1 is formed so as to continuously cover the cap layer CP1 and the partition 6.

The organic layer OR1, the upper electrode UE1, the cap layer CP1 and the sealing layer SE1 are formed in at least the entire display area DA and are provided in subpixels SP2 and SP3 as well as subpixel SP1. The organic layer OR1, the upper electrode UE1 and the cap layer CP1 are divided by the partition 6 having an overhang shape.

The materials which are emitted from evaporation sources when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

The sealing layer SE1 covers the cap layer CP1 located immediately above the partition 6, covers the cap layer CP1 located immediately above the lower electrode LE1 and is in contact with the partition 6.

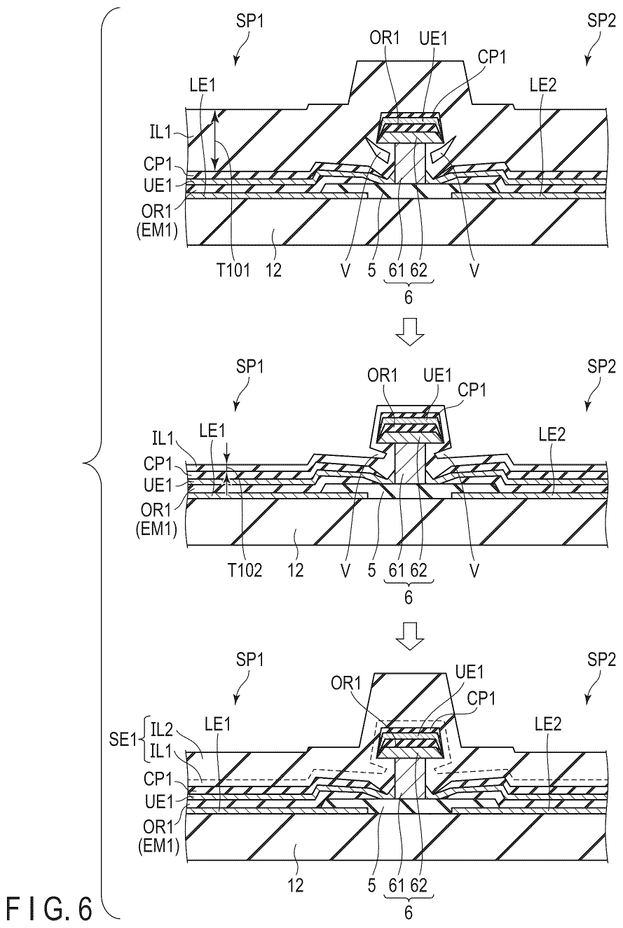

Here, the process of forming the sealing layer SE1 is further explained with reference to FIG. 6. FIG. 6 shows the section of the processing substrate over subpixel SP1 and subpixel SP2.

First, as shown in the upper part of FIG. 6, a first inorganic insulating layer IL1 is formed in a CVD device. The first inorganic insulating layer IL1 is formed of silicon nitride.

When this specification focuses attention on the first inorganic insulating layer IL1 located in subpixel SP1, the first inorganic insulating layer IL1 is in contact with the cap layer CP1, is in contact with a side surface of the lower portion 61 of the partition 6 and is in contact with the upper portion 62 of the partition 6. The first inorganic insulating layer IL1 has a closed void V under the upper portion 62. The first inorganic insulating layer IL1 has thickness T101 immediately above the lower electrode LE1.

Subsequently, as shown in the middle part of FIG. 6, anisotropic dry etching is performed for the entire first inorganic insulating layer IL1 without an intervention of a resist in a dry etching device. In anisotropic dry etching, side etching does not easily make progress compared to isotropic dry etching. Therefore, the thickness of the first inorganic insulating layer IL1 located immediately above each of the lower electrodes LE1 and LE2 is reduced, and the thickness of the first inorganic insulating layer IL1 located immediately above the upper portion 62 of the partition 6 is reduced. Further, the first inorganic insulating layer IL1 on the distal end side of each void V is removed, and each void V is opened. After the anisotropic dry etching is performed, the first inorganic insulating layer IL1 has thickness T102 immediately above the lower electrode LE1. Thickness T102 is less than thickness T101.

The first inorganic insulating layer IL1 located under the upper portion 62 of the partition 6 is not substantially removed. In other words, after the anisotropic dry etching, the first inorganic insulating layer IL1 covers the side surfaces of the lower portion 61 of the partition 6 and the bottom surface of the upper portion 62 of the partition 6. Subsequently, as shown in the lower part of FIG. 6, a second inorganic insulating layer IL2 is formed on the first inorganic insulating layer IL1 in a CVD device. The second inorganic insulating layer IL2 is formed of the same material as the first inorganic insulating layer IL1. Thus, the second inorganic insulating layer IL2 is formed of silicon nitride. When the first inorganic insulating layer IL1 and the second inorganic insulating layer IL2 are formed of the same material, the interface between them is not substantially recognized. In other words, although the sealing layer SE1 shown in FIG. 6 is the stacked layer body of the first inorganic insulating layer IL1 and the second inorganic insulating layer IL2, the sealing layer SE1 can be regarded as a single layer. For this reason, undesired reflection or scattering of light inside the sealing layer SE1 is prevented.

In the example shown in the figure, the sealing layer SE1 does not include any void under the upper portion 62. In this manner, as the sealing layer SE1 does not include any void, a crack based on a void can be prevented. It should be noted that the sealing layer SE1 may include a void smaller than each void V shown in the upper part of FIG. 6.

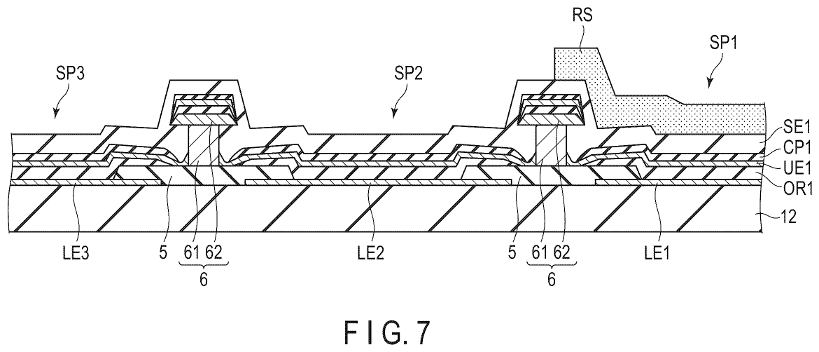

Subsequently, as shown in FIG. 7, a resist RS patterned into a predetermined shape is formed on the sealing layer SE1. The resist RS overlaps subpixel SP1 and part of the partition 6 around subpixel SP1.

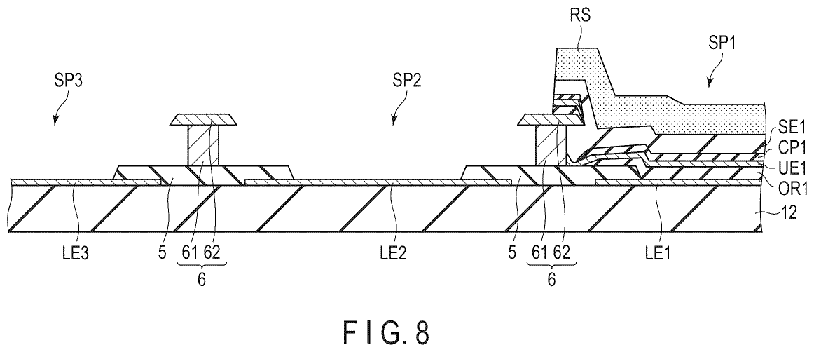

Subsequently, as shown in FIG. 8, the sealing layer SE1, cap layer CP1, upper electrode UE1 and organic layer OR1 exposed from the resist RS are removed in series by performing etching using the resist RS as a mask. In this manner, the lower electrode LE2 of subpixel SP2 and the lower electrode LE3 of subpixel SP3 are exposed.

Subsequently, the resist RS is removed. By this process, the display element 201 is formed in subpixel SP1.

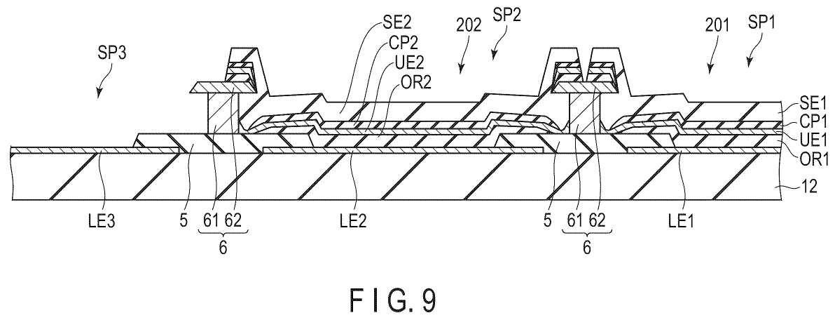

Subsequently, as shown in FIG. 9, the display element 202 is formed. The procedure of forming the display element 202 is similar to that of forming the display element 201. Specifically, the organic layer OR2 including the light emitting layer EM2, the upper electrode UE2, the cap layer CP2 and the sealing layer SE2 are formed in order on the lower electrode LE2. Subsequently, a resist is formed on the sealing layer SE2. The sealing layer SE2, the cap layer CP2, the upper electrode UE2 and the organic layer OR2 are patterned in series by etching using the resist as a mask. After this patterning, the resist is removed. In this manner, the display element 202 is formed in subpixel SP2, and the lower electrode LE3 of subpixel SP3 is exposed.

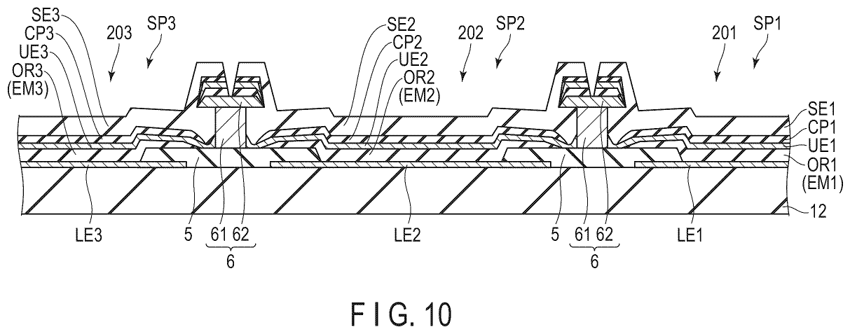

Subsequently, as shown in FIG. 10, the display element 203 is formed. The procedure of forming the display element 203 is similar to that of forming the display element 201. Specifically, the organic layer OR3 including the light emitting layer EM3, the upper electrode UE3, the cap layer CP3 and the sealing layer SE3 are formed in order on the lower electrode LE3. Subsequently, a resist is formed on the sealing layer SE3. The sealing layer SE3, the cap layer CP3, the upper electrode UE3 and the organic layer OR3 are patterned in series by etching using the resist as a mask. After this patterning, the resist is removed. By this process, the display element 203 is formed in subpixel SP3.

Subsequently, the resin layer 13, sealing layer 14 and resin layer 15 shown in FIG. 3 are formed in order. By this process, the display device DSP is completed.

In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

Now, this specification explains a configuration example of the display element 20.

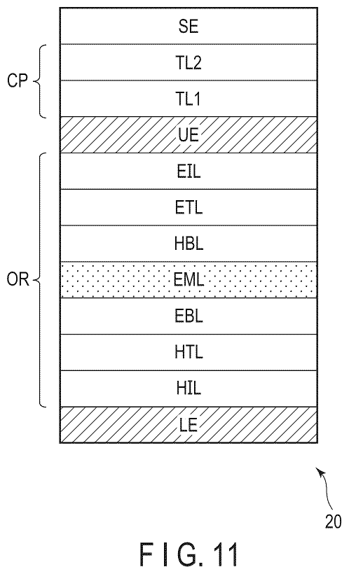

FIG. 11 is a diagram showing a configuration example of the display element 20.

The display element 20 shown in FIG. 11 could correspond to any one of the display elements 201, 202 and 203 described above.

Here, this specification explains an example in which a lower electrode LE corresponds to an anode and an upper electrode UE corresponds to a cathode.

The display element 20 comprises an organic layer OR (OR1, OR2 or OR3) between a lower electrode LE (LE1, LE2 or LE3) and an upper electrode UE (UE1, UE2 or UE3).

In the organic layer OR, a hole injection layer HIL, a hole transport layer HTL, an electron blocking layer EBL, a light emitting layer EML, a hole blocking layer HBL, an electron transport layer ETL and an electron injection layer EIL are stacked in this order.

It should be noted that the organic layer OR may include, in addition to the functional layers described above, other functional layers such as a carrier generation layer as needed, or at least one of the above functional layers may be omitted.

The light emitting layer EML corresponds to one of the light emitting layers EM1, EM2 and EM3 shown in FIG. 3.

A cap layer CP (CP1, CP2 or CP3) includes a first transparent layer TL1 and a second transparent layer TL2. The first transparent layer TL1 is provided on the upper electrode UE. The first transparent layer TL1 is a high-refractive layer having a refractive index which is higher than that of the upper electrode UE. The second transparent layer TL2 is provided on the first transparent layer TL1. The second transparent layer TL2 is a low-refractive layer having a refractive index which is less than that of the first transparent layer TL1. A sealing layer SE (SE1, SE2 or SE3) is provided on the second transparent layer TL2. It should be noted that the cap layer CP may be omitted.

It should be noted that the configuration of the organic layer OR is not limited to the configuration in which the organic layer OR comprises the light emitting layer EML consisting of a single layer as shown in the figure. The organic layer OR may comprise a plurality of light emitting layers.

Now, the manufacturing device 100 of the display device DSP is explained.

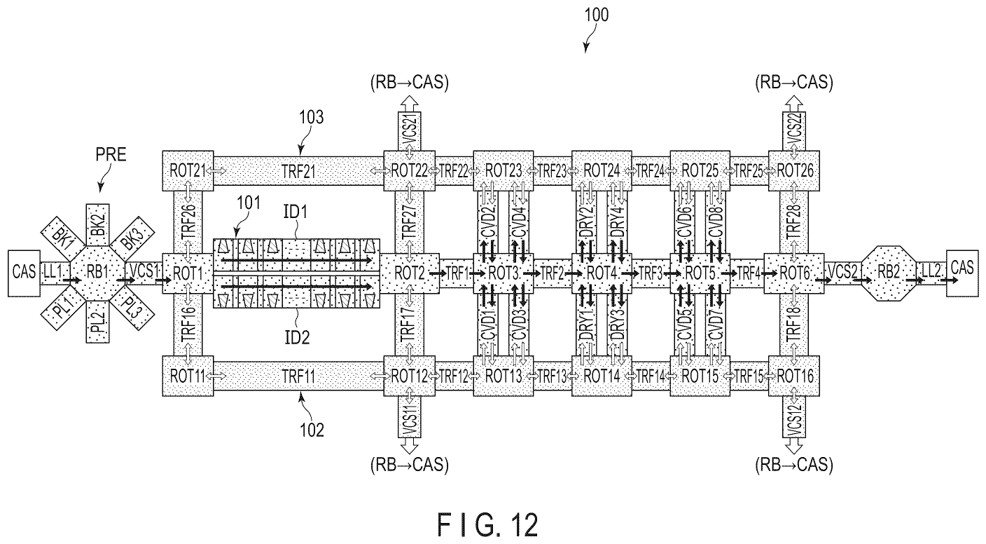

FIG. 12 is a diagram showing a configuration example of the manufacturing device 100. In the figure, the linear arrows indicate the conveyance direction of processing substrates.

The manufacturing device 100 comprises a main manufacturing line 101, and sub-lines 102 and 103 connected to the main manufacturing line 101. In the main manufacturing line 101, each processing substrate is conveyed from the left side to the right side of the figure.

The main manufacturing line 101 comprises a preprocessing portion PRE, in-line evaporation devices ID1 and ID2, CVD devices CVD1, CVD2, CVD3, CVD4, CVD5, CVD6, CVD7 and CVD8, and dry etching devices DRY1, DRY2, DRY3 and DRY4.

The preprocessing portion PRE is connected to a substrate cassette station CAS.

The evaporation devices ID and ID2 are located on the downstream side relative to the preprocessing portion PRE in the conveyance direction of processing substrates.

The CVD devices CVD1 to CVD4 are located on the downstream side relative to the evaporation devices ID1 and ID2.

The dry etching devices DRY1 to DRY4 are located on the downstream side relative to the CVD devices CVD1 to CVD4.

The CVD devices CVD5 to CVD8 are located on the downstream side relative to the dry etching devices DRY1 to DRY4.

It should be noted that, to manufacture display devices in the main manufacturing line 101, at least one evaporation device ID1, one CVD device CVD1, one dry etching device DRY1 and one CVD device CVD5 should be provided.

A plurality of processing substrates (each of which is the processing substrate SUB shown in FIG. 4) on which the lower electrode LE, the inorganic insulating layer 5, the partition 6 and the like are formed are accommodated in the substrate cassette station CAS.

The preprocessing portion PRE comprises a load lock chamber LL1 connected to the substrate cassette station CAS, a plurality of baking chambers BK1, BK2 and BK3 which perform a baking process for processing substrates, a plurality of plasma chambers PL1, PL2 and PL3 which perform a plasma process for processing substrates, and a conveyance robot chamber RB1.

The conveyance robot chamber RB1 is connected to the load lock chamber LL1, the baking chambers BK1 to BK3 and the plasma chambers PL1 to PL3 and comprises a robot which conveys processing substrates in a horizontal posture.

The evaporation devices ID1 and ID2 comprise the same configuration and comprise a plurality of evaporation chambers for forming an organic layer OR, an upper electrode UE and a cap layer CP, respectively. As described in detail later, the evaporation chambers are arranged unidirectionally in each of the evaporation devices ID1 and ID2. For example, each of the evaporation devices ID1 and ID2 is configured to form the organic layer OR1, upper electrode UE1 and cap layer CP1 shown in FIG. 5.

All of the CVD devices CVD1 to CVD4 comprise the same configuration, and are configured to form, for example, the first inorganic insulating layer IL1 shown in FIG. 6.

All of the dry etching devices DRY1 to DRY4 comprise the same configuration, and are configured to reduce the thickness of the first inorganic insulating layer IL1.

All of the CVD devices CVD5 to CVD8 comprise the same configuration, and are configured to form, for example, the second inorganic insulating layer IL2 shown in FIG. 6.

In the example shown in the figure, the main manufacturing line 101 further comprises a posture conversion chamber VCS1, rotation chambers ROT1, ROT2, ROT3, ROT4, ROT5 and ROT6, conveyance chambers TRF1, TRF2, TRF3 and TRF4, a posture conversion chamber VCS2, a conveyance robot chamber RB2 and a load lock chamber LL2.

The posture conversion chamber VCS1 is connected between the preprocessing portion PRE and the rotation chamber ROT1. The posture conversion chamber VCS1 comprises a mechanism for rotating each processing substrate which is conveyed in a horizontal posture in the preprocessing portion PRE by 90° to convert the posture of the processing substrate to a perpendicular posture. The posture conversion chamber VCS1 also comprises a mechanism which secures each processing substrate to a dedicated carrier by an electrostatic chuck. The posture of each processing substrate SUB which is carried into the rotation chamber ROT1 is a perpendicular posture.

All of the rotation chambers ROT1 to ROT6 comprise the same configuration and comprise a rotation mechanism. The rotation mechanism is configured to hold each processing substrate which is carried in in a perpendicular posture and rotate around a rotation axis perpendicular to the normal of each processing substrate. The rotation angles of the rotation mechanism are, for example, 90°, 180° and 270°. However, the rotation angles may be other angles.

The rotation chamber ROT1 is connected to the posture conversion chamber VCS1 and is also connected to the upstream side of the evaporation devices ID1 and ID2.

The rotation chamber ROT2 is connected to the downstream side of the evaporation devices ID1 and ID2.

The rotation chamber ROT3 is connected to the CVD devices CVD1 to CVD4.

The rotation chamber ROT4 is connected to the dry etching devices DRY1 to DRY4.

The rotation chamber ROT5 is connected to the CVD devices CVD5 to CVF8.

The rotation chamber ROT6 is located on the downstream side of the rotation chamber ROT5.

Each of the conveyance chambers TRF1 to TRF4 comprises a conveyance mechanism which conveys each processing substrate having a perpendicular posture unidirectionally.

The conveyance chamber TRF1 connects the rotation chamber ROT2 and the rotation chamber ROT3 to each other.

The conveyance chamber TRF2 connects the rotation chamber ROT3 and the rotation chamber ROT4 to each other.

The conveyance chamber TRF3 connects the rotation chamber ROT4 and the rotation chamber ROT5 to each other.

The conveyance chamber TRF4 connects the rotation chamber ROT5 and the rotation chamber ROT6 to each other.

In the main manufacturing line 101, each processing substrate is conveyed in a perpendicular posture in the evaporation devices ID1 and ID2, the CVD devices CVD1 to CVD8, the dry etching devices DRY1 to DRY4, the rotation chambers ROT1 to ROT6 and the conveyance chambers TRF1 to TRF4.

The posture conversion chamber VCS2 is connected to the rotation chamber ROT6. The posture conversion chamber VCS2 comprises a mechanism for rotating each processing substrate which is conveyed in a perpendicular posture in the rotation chamber ROT6 by 90° to convert the posture of the processing substrate to a horizontal posture. The posture conversion chamber VCS2 also comprises a mechanism which releases the securing applied by the electrostatic chuck and removes each processing substrate SUB from the carrier.

The conveyance robot chamber RB2 is connected to the posture conversion chamber VCS2 and the load lock chamber LL2 and comprises a robot which conveys processing substrates in a horizontal posture. The load lock chamber LL2 is connected to a substrate cassette station CAS.

The sub-line 102 comprises rotation chambers ROT11, ROT12, ROT13, ROT14, ROT15 and ROT16, conveyance chambers TRF11, TRF12, TRF13, TRF14, TRF15, TRF16, TRF17 and TRF18, and posture conversion chambers VCS11 and VCS12.

The sub-line 102 is connected to the CVD devices CVD1 and CVD3, is connected to the dry etching devices DRY1 and DRY3 and is connected to the CVD devices CVD5 and CVD7. The sub-line 102 is connected to the main manufacturing line 101 between the preprocessing portion PRE and the evaporation device ID1 and between the preprocessing portion PRE and the evaporation device ID2. The sub-line 102 is connected to the main manufacturing line 101 between the evaporation device ID1 and the CVD devices CVD1 to CVD4 and between the evaporation device ID2 and the CVD devices CVD1 to CVD4.

All of the rotation chambers ROT11 to ROT16 comprise the same configuration and comprise a rotation mechanism which can rotate while holding each processing substrate having a perpendicular posture in a manner similar to that of the rotation chamber ROT1 etc.

The rotation chamber ROT13 is connected to the CVD devices CVD1 and CVD3.

The rotation chamber ROT14 is connected to the dry etching devices DRY1 and DRY3.

The rotation chamber ROT15 is connected to the CVD devices CVD5 and CVD7.

Each of the conveyance chambers TRF11 to TRF18 comprises a conveyance mechanism which can convey processing substrates having a perpendicular posture bidirectionally.

The conveyance chamber TRF11 connects the rotation chamber ROT11 and the rotation chamber ROT12 to each other.

The conveyance chamber TRF12 connects the rotation chamber ROT12 and the rotation chamber ROT13 to each other.

The conveyance chamber TRF13 connects the rotation chamber ROT13 and the rotation chamber ROT14 to each other.

The conveyance chamber TRF14 connects the rotation chamber ROT14 and the rotation chamber ROT15 to each other.

The conveyance chamber TRF15 connects the rotation chamber ROT15 and the rotation chamber ROT16 to each other.

The conveyance chamber TRF16 connects the rotation chamber ROT1 and the rotation chamber ROT11 to each other.

The conveyance chamber TRF17 connects the rotation chamber ROT2 and the rotation chamber ROT12 to each other.

The conveyance chamber TRF18 connects the rotation chamber ROT6 and the rotation chamber ROT16 to each other.

The posture conversion chamber VCS11 is connected to the rotation chamber ROT12. The posture conversion chamber VCS12 is connected to the rotation chamber ROT16. Each of the posture conversion chambers VCS11 and VCS12 comprises a mechanism which converts the posture of each processing substrate which is conveyed in a perpendicular posture to a horizontal posture. Each of the posture conversion chambers VCS11 and VCS12 also comprises a mechanism which releases the securing applied by the electrostatic chuck and removes each processing substrate SUB from the carrier.

The sub-line 103 comprises rotation chambers ROT21, ROT22, ROT23, ROT24, ROT25 and ROT26, conveyance chambers TRF21, TRF22, TRF23, TRF24, TRF25, TRF26, TRF27 and TRF28, and posture conversion chambers VCS21 and VCS22.

The sub-line 103 is connected to the CVD devices CVD2 and CVD4, is connected to the dry etching devices DRY2 and DRY4 and is connected to the CVD devices CVD6 and CVD8. The sub-line 103 is connected to the main manufacturing line 101 between the preprocessing portion PRE and the evaporation device ID1 and between the preprocessing portion PRE and the evaporation device ID2. The sub-line 103 is connected to the main manufacturing line 101 between the evaporation device ID1 and the CVD devices CVD1 to CVD4 and between the evaporation device ID2 and the CVD devices CVD1 to CVD4.

All of the rotation chambers ROT21 to ROT26 comprise the same configuration and comprise a rotation mechanism which can rotate while holding each processing substrate having a perpendicular posture in a manner similar to that of the rotation chamber ROT1 etc.

The rotation chamber ROT23 is connected to the CVD devices CVD2 and CVD4.

The rotation chamber ROT24 is connected to the dry etching devices DRY2 and DRY4.

The rotation chamber ROT25 is connected to the CVD devices CVD6 and CVD8.

Each of the conveyance chambers TRF21 to TRF28 comprises a conveyance mechanism which can convey each processing substrate having a perpendicular posture bidirectionally.

The conveyance chamber TRF21 connects the rotation chamber ROT21 and the rotation chamber ROT22 to each other.

The conveyance chamber TRF22 connects the rotation chamber ROT22 and the rotation chamber ROT23 to each other.

The conveyance chamber TRF23 connects the rotation chamber ROT23 and the rotation chamber ROT24 to each other.

The conveyance chamber TRF24 connects the rotation chamber ROT24 and the rotation chamber ROT25 to each other.

The conveyance chamber TRF25 connects the rotation chamber ROT25 and the rotation chamber ROT26 to each other.

The conveyance chamber TRF26 connects the rotation chamber ROT1 and the rotation chamber ROT21 to each other.

The conveyance chamber TRF27 connects the rotation chamber ROT2 and the rotation chamber ROT22 to each other.

The conveyance chamber TRF28 connects the rotation chamber ROT6 and the rotation chamber ROT26 to each other.

The posture conversion chamber VCS21 is connected to the rotation chamber ROT22. The posture conversion chamber VCS22 is connected to the rotation chamber ROT26. Each of the posture conversion chambers VCS21 and VCS22 comprises a mechanism which converts the posture of each processing substrate which is conveyed in a perpendicular posture to a horizontal posture. Each of the posture conversion chambers VCS21 and VCS22 also comprises a mechanism which releases the securing applied by the electrostatic chuck and removes each processing substrate from the carrier.

Although not described in detail, the posture conversion chambers VCS11, VCS12, VCS21 and VCS22 are connected to respective conveyance robot chambers RB. The conveyance robot chambers RB are connected to respective load lock chambers connected to respective substrate cassette stations CAS.

These sub-lines 102 and 103 form a detour which is different from the main manufacturing line 101 as a conveyance path to convey processing substrates. The main manufacturing line 101 and the sub-lines 102 and 103 form a loop conveyance path by connecting the sub-lines 102 and 103 to the main manufacturing line 101.

In the example shown in the figure, the manufacturing device 100 comprises two sub-lines 102 and 103. However, a loop conveyance path can be formed as long as the manufacturing device 100 comprises at least one sub-line 102.

In the configuration example shown in FIG. 12, for example, the evaporation device ID1 corresponds to a first evaporation device, and the evaporation device ID2 corresponds to a second evaporation device. Each of the CVD devices CVD1 to CVD4 corresponds to a first CVD device. Each of the CVD devices CVD5 to CVD8 corresponds to a second CVD device.

The rotation chamber ROT1 corresponds to a first rotation chamber. The rotation chamber ROT2 corresponds to a second rotation chamber. The rotation chamber ROT3 corresponds to a third rotation chamber. The rotation chamber ROT4 corresponds to a fourth rotation chamber. The rotation chamber ROT5 corresponds to a fifth rotation chamber. The rotation chamber ROT6 corresponds to a sixth rotation chamber. The rotation chamber ROT11 corresponds to a seventh rotation chamber. The rotation chamber ROT12 corresponds to an eighth rotation chamber. The rotation chamber ROT13 corresponds to a ninth rotation chamber. The rotation chamber ROT14 corresponds to a tenth rotation chamber. The rotation chamber ROT15 corresponds to an eleventh rotation chamber. The rotation chamber ROT16 corresponds to a twelfth rotation chamber.

The conveyance chamber TRF1 corresponds to a first conveyance chamber. The conveyance chamber TRF2 corresponds to a second conveyance chamber. The conveyance chamber TRF3 corresponds to a third conveyance chamber. The conveyance chamber TRF4 corresponds to a fourth conveyance chamber. The conveyance chamber TRF11 corresponds to a fifth conveyance chamber. The conveyance chamber TRF12 corresponds to a sixth conveyance chamber. The conveyance chamber TRF13 corresponds to a seventh conveyance chamber. The conveyance chamber TRF14 corresponds to an eighth conveyance chamber. The conveyance chamber TRF15 corresponds to a ninth conveyance chamber. The conveyance chamber TRF16 corresponds to a tenth conveyance chamber. The conveyance chamber TRF17 corresponds to an eleventh conveyance chamber. The conveyance chamber TRF18 corresponds to a twelfth conveyance chamber.

According to this manufacturing device 100, a plurality of baking chambers and a plurality of plasma chambers are provided in the preprocessing portion PRE such that the preprocessing of a plurality of processing substrates can be simultaneously performed.

In the evaporation devices ID1 and ID2, the formation of an organic layer OR, an upper electrode UE and a cap layer CP can be simultaneously performed for a plurality of processing substrates.

In the CVD devices CVD1 to CVD4, the formation of the first inorganic insulating layer IL1 can be simultaneously performed for a plurality of processing substrates.

In the dry etching devices DRY1 to DRY4, the reduction in the thickness of the first inorganic insulating layer IL1 can be simultaneously performed for a plurality of processing substrates.

In the CVD devices CVD5 to CVD8, the formation of the second inorganic insulating layer IL2 can be simultaneously performed for a plurality of processing substrates.

In this manner, the manufacturing yield can be improved.

Since the manufacturing device 100 comprises a plurality of devices which perform the same process, even if one of the devices goes wrong or is subjected to maintenance, the main manufacturing line 101 can be continuously operated without stopping manufacturing.

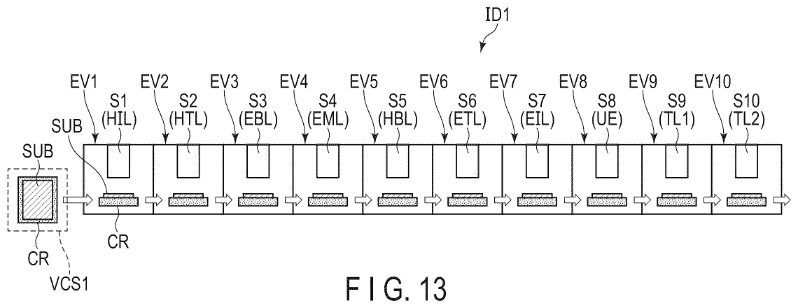

FIG. 13 is a diagram showing a configuration example of the evaporation device ID1.

The evaporation device ID1 comprises a plurality of evaporation chambers EV1, EV2, EV3, EV4, EV5, EV6, EV7, EV8, EV9 and EV10. These evaporation chambers EV1 to EV10 are arranged in a single direction.

The evaporation chamber EV1 comprises an evaporation source S1. The evaporation source S1 is configured to emit a material for forming a hole injection layer HIL.

The evaporation chamber EV2 comprises an evaporation source S2. The evaporation source S2 is configured to emit a material for forming a hole transport layer HTL.

The evaporation chamber EV3 comprises an evaporation source S3. The evaporation source S3 is configured to emit a material for forming an electron blocking layer EBL.

The evaporation chamber EV4 comprises an evaporation source S4. The evaporation source S4 is configured to emit a material for forming a light emitting layer EML.

The evaporation chamber EV5 comprises an evaporation source S5. The evaporation source S5 is configured to emit a material for forming a hole blocking layer HBL.

The evaporation chamber EV6 comprises an evaporation source S6. The evaporation source S6 is configured to emit a material for forming an electron transport layer ETL.

The evaporation chamber EV7 comprises an evaporation source S7. The evaporation source S7 is configured to emit a material for forming an electron injection layer EIL.

The evaporation chamber EV8 comprises an evaporation source S8. The evaporation source S8 is configured to emit a material for forming an upper electrode UE.

The evaporation chamber EV9 comprises an evaporation source S9. The evaporation source S9 is configured to emit a material for forming a first transparent layer TL1.

The evaporation chamber EV10 comprises an evaporation source S10. The evaporation source S10 is configured to emit a material for forming a second transparent layer TL2.

Before a processing substrate SUB is carried into the evaporation device ID1, the processing substrate SUB is conveyed in a horizontal posture and is secured to the carrier CR in the posture conversion chamber VCS1. In the posture conversion chamber VCS1, the posture of the processing substrate SUB is converted to a perpendicular posture. The processing substrate SUB which is in a perpendicular posture is carried into the evaporation device ID1. In the evaporation device ID1, the materials are deposited in the evaporation chambers in series while the processing substrate SUB is conveyed in a perpendicular posture.

In the configuration example shown in FIG. 13, for example, the evaporation chamber EV1 corresponds to a first evaporation chamber. The evaporation chamber EV2 corresponds to a second evaporation chamber. The evaporation chamber EV3 corresponds to a third evaporation chamber. The evaporation chamber EV4 corresponds to a fourth evaporation chamber. The evaporation chamber EV5 corresponds to a fifth evaporation chamber. The evaporation chamber EV6 corresponds to a sixth evaporation chamber. The evaporation chamber EV7 corresponds to a seventh evaporation chamber. The evaporation chamber EV8 corresponds to an eighth evaporation chamber. The evaporation chamber EV9 corresponds to a ninth evaporation chamber. The evaporation chamber EV10 corresponds to a tenth evaporation chamber.

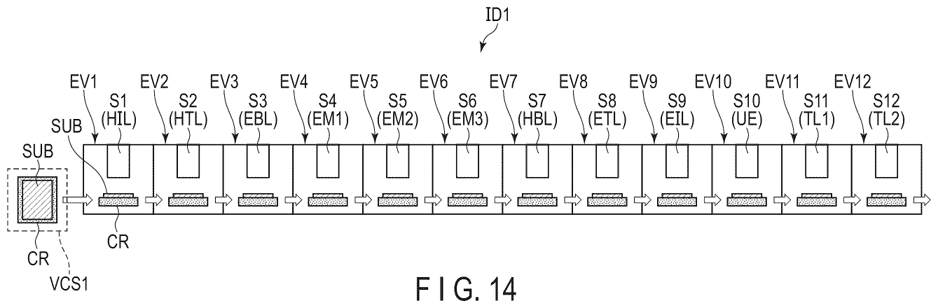

FIG. 14 is a diagram showing another configuration example of the evaporation device ID1.

The evaporation device ID1 comprises a plurality of evaporation chambers EV1, EV2, EV3, EV4, EV5, EV6, EV7, EV8, EV9, EV10, EV11 and EV12. These evaporation chambers EV1 to EV12 are arranged in a single direction.

The evaporation chamber EV1 comprises an evaporation source S1. The evaporation source S1 is configured to emit a material for forming a hole injection layer HIL.

The evaporation chamber EV2 comprises an evaporation source S2. The evaporation source S2 is configured to emit a material for forming a hole transport layer HTL.

The evaporation chamber EV3 comprises an evaporation source S3. The evaporation source S3 is configured to emit a material for forming an electron blocking layer EBL.

The evaporation chamber EV4 comprises an evaporation source S4. The evaporation source S4 is configured to emit a material for forming a light emitting layer EM1.

The evaporation chamber EV5 comprises an evaporation source S5. The evaporation source S5 is configured to emit a material for forming a light emitting layer EM2.

The evaporation chamber EV6 comprises an evaporation source S6. The evaporation source S6 is configured to emit a material for forming a light emitting layer EM3.

The materials emitted from the evaporation sources S4, S5 and S6 are light emitting materials which emit colors different from each other.

The evaporation chamber EV7 comprises an evaporation source S7. The evaporation source S7 is configured to emit a material for forming a hole blocking layer HBL.

The evaporation chamber EV8 comprises an evaporation source S8. The evaporation source S8 is configured to emit a material for forming an electron transport layer ETL.

The evaporation chamber EV9 comprises an evaporation source S9. The evaporation source S9 is configured to emit a material for forming an electron injection layer EIL.

The evaporation chamber EV10 comprises an evaporation source S10. The evaporation source S10 is configured to emit a material for forming an upper electrode UE.

The evaporation chamber EV11 comprises an evaporation source S11. The evaporation source S11 is configured to emit a material for forming a first transparent layer TL1.

The evaporation chamber EV12 comprises an evaporation source S12. The evaporation source S12 is configured to emit a material for forming a second transparent layer TL2.

Before a processing substrate SUB is carried into the evaporation device ID1, the processing substrate SUB is conveyed in a horizontal posture and is secured to the carrier CR in the posture conversion chamber VCS1. In the posture conversion chamber VCS1, the posture of the processing substrate SUB is converted to a perpendicular posture. The processing substrate SUB which is in a perpendicular posture is carried into the evaporation device ID1.

When the display element 201 is formed in this evaporation device ID1, the materials are deposited in series in the evaporation chambers EV1 to EV4 while the processing substrate SUB is conveyed in a perpendicular posture. Subsequently, the processing substrate SUB is conveyed without the deposition of the materials in the evaporation chambers EV5 and EV6. Subsequently, the materials are deposited in series in the evaporation chambers EV7 to EV12.

When the display element 202 is formed, the materials are deposited in series in the evaporation chambers EV1 to EV3 while the processing substrate SUB is conveyed in a perpendicular posture. Subsequently, the processing substrate SUB is conveyed without the deposition of the material in the evaporation chamber EV4. Subsequently, the material is deposited in the evaporation chamber EV5. Subsequently, the processing substrate SUB is conveyed without the deposition of the material in the evaporation chamber EV6. Subsequently, the materials are deposited in series in the evaporation chambers EV7 to EV12.

When the display element 203 is formed, the materials are deposited in series in the evaporation chambers EV1 to EV3 while the processing substrate SUB is conveyed in a perpendicular posture. Subsequently, the processing substrate SUB is conveyed without the deposition of the materials in the evaporation chambers EV4 and EV5. Subsequently, the materials are deposited in series in the evaporation chambers EV6 to EV12.

In the configuration example shown in FIG. 14, for example, the evaporation chamber EV1 corresponds to the first evaporation chamber. The evaporation chamber EV2 corresponds to the second evaporation chamber. The evaporation chamber EV3 corresponds to the third evaporation chamber. The evaporation chamber EV4 corresponds to the fourth evaporation chamber. The evaporation chamber EV5 corresponds to the fifth evaporation chamber. The evaporation chamber EV6 corresponds to the sixth evaporation chamber. The evaporation chamber EV7 corresponds to the seventh evaporation chamber. The evaporation chamber EV8 corresponds to the eighth evaporation chamber. The evaporation chamber EV9 corresponds to the ninth evaporation chamber. The evaporation chamber EV10 corresponds to the tenth evaporation chamber. The evaporation chamber EV11 corresponds to an eleventh evaporation chamber. The evaporation chamber EV12 corresponds to a twelfth evaporation chamber. The light emitting layer EM1 corresponds to a first light emitting layer. The light emitting layer EM2 corresponds to a second light emitting layer. The light emitting layer EM3 corresponds to a third light emitting layer.

According to the configuration example shown in FIG. 14, the evaporation device ID1 can be applied to form all of the display elements 201 to 203. Thus, the scale of the manufacturing device 100 can be reduced as individual main manufacturing lines 101 are not needed to form the display elements 201 to 203.

The detailed explanation of the evaporation device ID2 is omitted here. It should be noted that the evaporation device ID2 is configured in a manner similar to that of the evaporation device ID1 shown in FIG. 13 or FIG. 14.

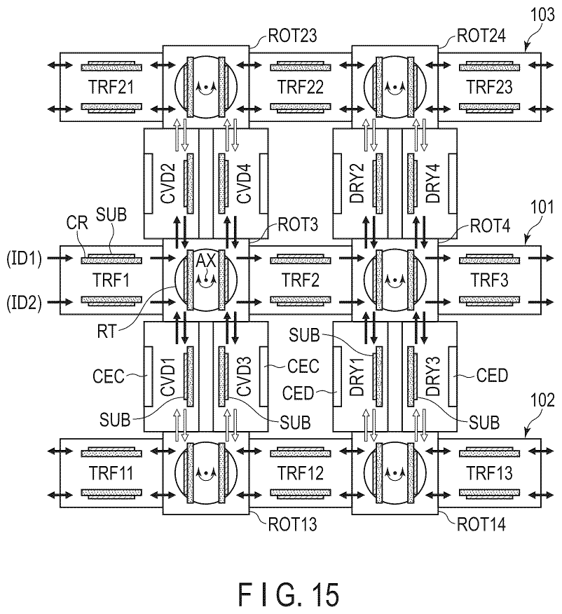

FIG. 15 is a diagram showing the outline of the CVD devices and the dry etching devices.

Each of the CVD devices CVD1 to CVD4 comprises a counter-electrode CEC which faces the processing substrate SUB. The counter-electrode CEC is an electrode to which voltage necessary to turn a source gas into plasma is applied between the counter-electrode CEC and the processing substrate SUB.

When this specification focuses attention on the CVD devices CVD1 and CVD3, each of the CVD devices CVD1 and CVD3 comprises a gate connected to the rotation chamber ROT3 and a gate connected to the rotation chamber ROT13. Thus, the processing substrate SUB can be carried into and out of each of the CVD devices CVD1 and CVD3 with respect to the rotation chamber ROT3 and can be also carried into and out of each of the CVD devices CVD1 and CVD3 with respect to the rotation chamber ROT13.

In each of the CVD devices CVD1 and CVD3, the counter-electrode CEC is provided on the external side of the conveyance path of the processing substrate SUB.

The processing substrate SUB can be carried into and out of each of the CVD devices CVD2 and CVD4 with respect to the rotation chamber ROT3 and can be also carried into and out of each of the CVD devices CVD2 and CVD4 with respect to the rotation chamber ROT23.

Each of the dry etching devices DRY1 to DRY4 comprises a counter-electrode CED which faces the processing substrate SUB. The counter-electrode CED is an electrode to which voltage necessary to turn an etching gas into plasma is applied between the counter-electrode CED and the processing substrate SUB.

When this specification focuses attention on the dry etching devices DRY1 and DRY3, each of the dry etching devices DRY1 and DRY3 comprises a gate connected to the rotation chamber ROT4 and a gate connected to the rotation chamber ROT14. Thus, the processing substrate SUB can be carried into and out of each of the dry etching devices DRY1 and DRY3 with respect to the rotation chamber ROT4 and can be also carried into and out of each of the dry etching devices DRY1 and DRY3 with respect to the rotation chamber ROT14.

In each of the dry etching devices DRY1 and DRY3, the counter-electrode CED is provided on the external side of the conveyance path of the processing substrate SUB.

The processing substrate SUB can be carried into and out of each of the dry etching devices DRY2 and DRY4 with respect to the rotation chamber ROT4 and can be also carried into and out of each of the dry etching devices DRY2 and DRY4 with respect to the rotation chamber ROT24.

In the main manufacturing line 101, each of the conveyance chambers TRF1, TRF2 and TRF3 comprises a conveyance path for unidirectionally conveying a processing substrate SUB which is conveyed from the evaporation device ID1, and a conveyance path for unidirectionally conveying a processing substrate SUB which is conveyed from the evaporation device ID2. In the conveyance chamber TRF1 etc., the carrier CR is located on the internal side of the conveyance path, and the processing substrate SUB is located on the external side of the conveyance path. The rotation chamber ROT3 comprises a rotation mechanism RT which can rotate around a rotation axis AX. The rotation mechanism RT can rotate bidirectionally, that is, clockwise and counterclockwise, as shown by the arrows of the figure. The rotation chamber ROT4 is configured in a manner similar to that of the rotation chamber ROT3. In the rotation chamber ROT3 etc., the carrier CR faces the rotation axis AX.

In the sub-line 102, each of the conveyance chambers TRF11, TRF12 and TRF13 comprises two conveyance paths for conveying each processing substrate SUB bidirectionally. The rotation chambers ROT13 and ROT14 are configured in a manner similar to that of the rotation chamber ROT3.

In the sub-line 103, each of the conveyance chambers TRF21, TRF22 and TRF23 comprises two conveyance paths for conveying each processing substrate SUB bidirectionally. The rotation chambers ROT23 and ROT24 are configured in a manner similar to that of the rotation chamber ROT3.

Here, this specification returns to FIG. 12 to explain the flow of each processing substrate when the display device DSP is manufactured in the manufacturing device 100.

First, the flow of each processing substrate in a normal mode is explained.

A processing substrate extracted from the substrate cassette station CAS is carried into the load lock chamber LL1. Subsequently, the processing substrate is carried into one of the baking chambers BK1 to BK3 and baked. Subsequently, the processing substrate is carried into one of the plasma chambers PL1 to PL3 and subjected to plasma treatment.

Subsequently, the processing substrate is carried into the posture conversion chamber VCS1 in a horizontal posture and is secured to the carrier. Further, the posture of the processing substrate is converted to a perpendicular posture. Subsequently, the processing substrate is carried into the evaporation device ID1 or the evaporation device ID2 via the rotation chamber ROT1. In the evaporation device ID1 or the evaporation device ID2, an organic layer OR, an upper electrode UE and a cap layer CP are formed in order on the processing substrate.

Subsequently, the processing substrate goes through the rotation chamber ROT2 and the conveyance chamber TRF1 and is carried into the rotation chamber ROT3. In the rotation chamber ROT3, the rotation mechanism which holds the processing substrate rotates 90°. Subsequently, the processing substrate is carried into one of the CVD devices CVD1 to CVD4. In each of the CVD devices CVD1 and CVD4, the first inorganic insulating layer IL1 is formed on the processing substrate.

Subsequently, the processing substrate is carried into the rotation chamber ROT3 again. In the rotation chamber ROT3, the rotation mechanism which holds the processing substrate rotates 90°. Subsequently, the processing substrate is carried into the rotation chamber ROT4 via the conveyance chamber TRF2. In the rotation chamber ROT4, the rotation mechanism which holds the processing substrate rotates 90°. Subsequently, the processing substrate is carried into one of the dry etching devices DRY1 to DRY4. In the dry etching devices DRY1 to DRY4, the thickness of the first inorganic insulating layer IL1 is reduced.

Subsequently, the processing substrate is carried into the rotation chamber ROT4 again. In the rotation chamber ROT4, the rotation mechanism which holds the processing substrate rotates 90°.

Subsequently, the processing substrate is carried into the rotation chamber ROT5 via the conveyance chamber TRF3. In the rotation chamber ROT5, the rotation mechanism which holds the processing substrate rotates 90°. Subsequently, the processing substrate is carried into one of the CVD devices CVD5 to CVD8. In each of the CVD devices CVD5 and CVD8, the second inorganic insulating layer IL2 is formed on the processing substrate.

Subsequently, the processing substrate is carried into the rotation chamber ROT 5 again. In the rotation chamber ROT5, the rotation mechanism which holds the processing substrate rotates 90°. Subsequently, the processing substrate goes through the conveyance chamber TRF4 and the rotation chamber ROT6, is carried into the posture conversion chamber VCS2 in a perpendicular posture and is released from the carrier. Further, the posture of the processing substrate is converted to a horizontal posture. Subsequently, the processing substrate is carried into the load lock chamber LL2. Subsequently, the processing substrate is carried into the substrate cassette station CAS.

Now, this specification explains several cases with respect to a detour mode which detours a processing substrate when a failure occurs in part of the devices which constitute the manufacturing device 100.

(Case 1) when the Dry Etching Devices DRY1 to DRY4 Cannot be Used.

For example, a processing substrate which was carried out of the evaporation device ID1 goes through the rotation chamber ROT2, the conveyance chamber TRF27, the rotation chamber ROT22 and the posture conversion chamber VCS21 and is collected by the substrate cassette station CAS.

A processing substrate which was carried out of the evaporation device ID2 goes through the rotation chamber ROT2, the conveyance chamber TRF17, the rotation chamber ROT12 and the posture conversion chamber VCS11 and is collected by the substrate cassette station CAS.

Each of processing substrates which were processed in the CVD devices CVD1 and CVD3 goes through the rotation chamber ROT13, the conveyance chamber TRF12, the rotation chamber ROT12 and the posture conversion chamber VCS11 and is collected by the substrate cassette station CAS.

Each of processing substrates which were processed in the CVD devices CVD2 and CVD4 goes through the rotation chamber ROT23, the conveyance chamber TRF22, the rotation chamber ROT22 and the posture conversion chamber VCS21 and is collected by the substrate cassette station CAS.

In this manner, each processing substrate which is in the middle of manufacturing can be promptly collected, and thus, the time required until restoration can be reduced.

(Case 2-1) when the CVD Devices CVD5 to CVD8 Cannot be Used.

Each of processing substrates which were processed in the dry etching devices DRY1 and DRY3 goes through the rotation chamber ROT14, the conveyance chamber TRF14, the rotation chamber ROT15, the conveyance chamber TRF15, the rotation chamber ROT16 and the posture conversion chamber VCS12 and is collected by the substrate cassette station CAS.

Each of processing substrates which were processed in the dry etching devices DRY2 and DRY4 goes through the rotation chamber ROT24, the conveyance chamber TRF24, the rotation chamber ROT25, the conveyance chamber TRF25, the rotation chamber ROT26 and the posture conversion chamber VCS22 and is collected by the substrate cassette station CAS.

In this manner, each processing substrate which is in the middle of manufacturing can be promptly collected, and thus, the time required until restoration can be reduced.

(Case 2-2) when the CVD Devices CVD5 to CVD8 Cannot be Used.

Each of processing substrates which were processed in the dry etching devices DRY1 and DRY3 goes through the rotation chamber ROT14, the conveyance chamber TRF13 and the rotation chamber ROT13 and is carried into one of the CVD devices CVD1 and CVD3. Subsequently, the second inorganic insulating layer IL2 is formed on the processing substrate in one of the CVD devices CVD1 and CVD3. Thus, the CVD devices CVD1 to CVD4 are used in place of the CVD devices CVD5 to CVD8.

Thus, even if a failure occurs in part of the manufacturing device, the manufacturing of the display device can be continued.

(Case 3) when the Rotation Chamber ROT4 Cannot be Used.

Each of processing substrates which were processed in the CVD devices CVD1 and CVD3 goes through the rotation chamber ROT13, the conveyance chamber TRF13 and the rotation chamber ROT14 and is carried into one of the dry etching devices DRY1 and DRY3. Each of processing substrates which were processed in the dry etching devices DRY1 and DRY3 goes through the rotation chamber ROT14, the conveyance chamber TRF14 and the rotation chamber ROT15 and is carried into one of the CVD devices CVD5 and CVD7.

Thus, even when one of the conveyance systems of the main manufacturing line 101 cannot be used, the manufacturing of the display device can be continued by conveying the processing substrate via the sub-lines 102 and 103.

### (Case 4) Confirmation of Deposited Layers

In a mode which confirms the state of the deposited layers (the organic layer OR, upper electrode UE and cap layer CP) formed in the evaporation device ID1 before a normal mode is started, each processing substrate which was carried out of the evaporation device ID1 goes through the rotation chamber ROT2, the conveyance chamber TRF27, the rotation chamber ROT22 and the posture conversion chamber VCS21 and is connected by the substrate cassette station CAS.

By this configuration, the state of the deposited layers can be confirmed without being affected by the other layers.

### (Case 5) Confirmation of Thickness of Sealing Layer

In a mode which confirms the thickness of the first inorganic insulating layer IL1 formed in the CVD devices CVD1 and CVD3 before a normal mode is started, each processing substrate which was carried out of the rotation chamber ROT1 goes through the conveyance chamber TRF16, the rotation chamber ROT11, the conveyance chamber TRF11, the rotation chamber ROT12, the conveyance chamber TRF12 and the rotation chamber ROT13 and is carried into one of the CVD devices CVD1 and CVD3. Each processing substrate in which the first inorganic insulating layer IL1 is formed in the CVD devices CVD1 and CVD3 goes through the rotation chamber ROT13, the conveyance chamber TRF12, the rotation chamber ROT12 and the posture conversion chamber VCS11 and is collected by the substrate cassette station CAS.

By this configuration, the thickness of the first inorganic insulating layer IL1 can be confirmed without being affected by the other layers.

Now, this specification explains another configuration example of the manufacturing device 100.

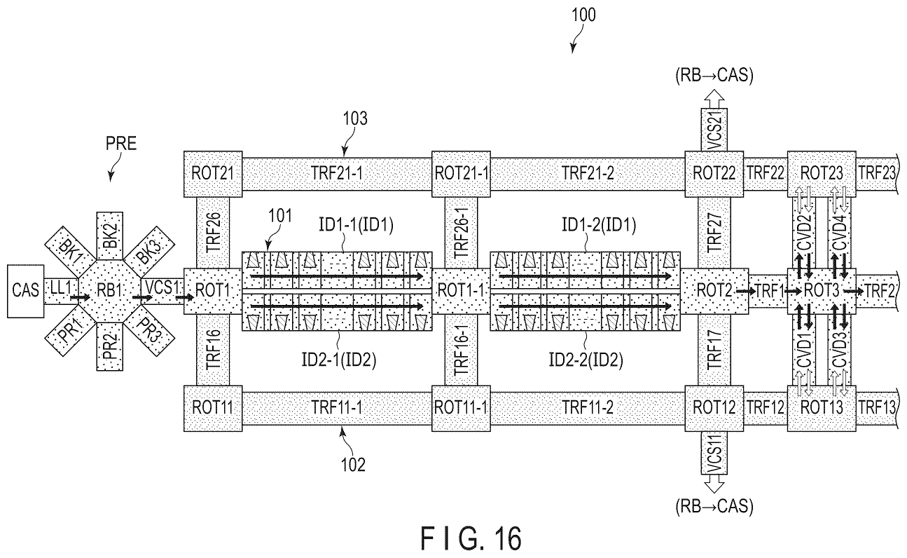

FIG. 16 is a diagram showing another configuration example of the manufacturing device 100. It should be noted that FIG. 16 shows the section from the preprocessing portion PRE to the CVD devices CVD1 to CVD4 in the manufacturing device 100 and omits the illustrations of the devices located on the downstream side from the dry etching devices DRY1 to DRY4.

The configuration example shown in FIG. 16 is different from that shown in FIG. 12 in respect that the sub-lines 102 and 103 are connected to the middle portions of the evaporation devices ID1 and ID2.

The main manufacturing line 101 comprises a rotation chamber ROT1-1 located in the middle portion of the evaporation device ID1 and the middle portion of the evaporation device ID2.

The evaporation device ID1 has a chamber group ID1-1 in which a plurality of evaporation chambers are arranged, and a chamber group ID1-2 in which a plurality of evaporation chambers are arranged. For example, the chamber group ID1-1 consists of the evaporation chambers EV1 to EV5 shown in FIG. 13. The chamber group ID1-2 consists of the evaporation chambers EV6 to EV10 shown in FIG. 13.

The evaporation device ID2 has a chamber group ID2-1 in which a plurality of evaporation chambers are arranged, and a chamber group ID2-2 in which a plurality of evaporation chambers are arranged. The rotation chamber ROT1-1 is connected between the chamber group ID1-1 and the chamber group ID1-2 and is connected between the chamber group ID2-1 and the chamber group ID2-2. The rotation chamber ROT1-1 is also connected to the sub-lines 102 and 103.

The sub-line 102 comprises conveyance chambers TRF11-1 and TRF11-2, a rotation chamber ROT11-1 and a conveyance chamber TRF16-1 between the rotation chamber ROT11 and the rotation chamber ROT12.

The conveyance chamber TRF11-1 connects the rotation chamber ROT11 and the rotation chamber ROT11-1 to each other.

The conveyance chamber TRF11-2 connects the rotation chamber ROT11-1 and the rotation chamber ROT12 to each other.

The conveyance chamber TRF16-1 connects the rotation chamber ROT1-1 and the rotation chamber ROT11-1 to each other.

The sub-line 103 comprises conveyance chambers TRF21-1 and TRF21-2, a rotation chamber ROT21-1 and a conveyance chamber TRF26-1 between the rotation chamber ROT21 and the rotation chamber ROT22.

The conveyance chamber TRF21-1 connects the rotation chamber ROT21 and the rotation chamber ROT21-1 to each other.

The conveyance chamber TRF21-2 connects the rotation chamber ROT21-1 and the rotation chamber ROT22 to each other.

The conveyance chamber TRF26-1 connects the rotation chamber ROT1-1 and the rotation chamber ROT21-1 to each other.

In the configuration example shown in FIG. 16, for example, the rotation chamber ROT1-1 corresponds to a thirteenth rotation chamber.

In this configuration example, effects similar to those of the configuration example described above are obtained.

In addition, when part of the evaporation chambers of the evaporation devices ID1 and ID2 cannot be used, each processing device which is in the middle of manufacturing can be promptly collected.

Further, when part of the evaporation chambers of the chamber group ID1-1 cannot be used, the chamber group ID2-1 can be used in place of the chamber group ID1-1. Similarly, when part of the evaporation chambers of the chamber group ID2-2 cannot be used, the chamber group ID1-2 can be used in place of the chamber group ID2-2. In this manner, even if a failure occurs in part of the evaporation chambers, the manufacturing of the display device can be continued.

As described above, the embodiments can provide a manufacturing device of a display device and a manufacturing method of a display device such that the reduction in the manufacturing yield can be prevented.

All of the manufacturing devices and manufacturing methods that can be implemented by a person of ordinary skill in the art through arbitrary design changes to the manufacturing device and manufacturing method described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A manufacturing device of a display device, comprising:
a main manufacturing line which manufactures a display device while conveying a processing substrate in which a lower electrode is formed; and
a sub-line connected to the main manufacturing line, wherein
the main manufacturing line comprises:
a preprocessing portion which performs preprocessing for the processing substrate;
an in-line first evaporation device which is located on a downstream side in a conveyance direction of the processing substrate relative to the preprocessing portion and has a plurality of evaporation chambers for forming an organic layer, an upper electrode and a cap layer on the lower electrode in order;
at least one first CVD device which is located on a downstream side of the first evaporation device and is provided for forming a first inorganic insulating layer of a sealing layer on the cap layer;
at least one dry etching device which is located on a downstream side of the first CVD device and is provided for reducing a thickness of the first inorganic insulating layer; and
at least one second CVD device which is located on a downstream side of the dry etching device and is provided for forming a second inorganic insulating layer of the sealing layer on the first inorganic insulating layer,
the sub-line forms a detour which is different from the main manufacturing line as a conveyance path for conveying the processing substrate, and
the main manufacturing line and the sub-line form a loop conveyance path.

2. The manufacturing device of claim 1, wherein
the first CVD device, the dry etching device and the second CVD device are connected to the sub-line.

3. The manufacturing device of claim 1, wherein
the sub-line is connected to the main manufacturing line between the preprocessing portion and the first evaporation device and between the first evaporation device and the first CVD device.

4. The manufacturing device of claim 1, wherein
the main manufacturing line further comprises:
an line-line second evaporation device comprising a plurality of evaporation chambers for forming the organic layer, the upper electrode and the cap layer on the lower electrode;
a first rotation chamber connected to an upstream side of the first evaporation device and the second evaporation device and also connected to the sub-line; and
a second rotation chamber connected to a downstream side of the first evaporation device and the second evaporation device and also connected to the sub-line.

5. The manufacturing device of claim 4, wherein
the main manufacturing line further comprises:
a third rotation chamber connected to the first CVD device;
a fourth rotation chamber connected to the dry etching device; and
a fifth rotation chamber connected to the second CVD device.

6. The manufacturing device of claim 5, wherein
the main manufacturing line further comprises:
a first conveyance chamber which connects the second rotation chamber and the third rotation chamber to each other;
a second conveyance chamber which connects the third rotation chamber and the fourth rotation chamber to each other;
a third conveyance chamber which connects the fourth rotation chamber and the fifth rotation chamber to each other;
a sixth rotation chamber; and
a fourth conveyance chamber which connects the fifth rotation chamber and the sixth rotation chamber to each other.

7. The manufacturing device of claim 4, wherein
the main manufacturing line further comprises a posture conversion chamber which is connected between the preprocessing portion and the first rotation chamber and converts a posture of the processing substrate conveyed in a horizontal posture in the preprocessing portion to a perpendicular posture, and
the processing substrate is conveyed in a perpendicular posture in the first evaporation device, the first CVD device, the dry etching device and the second CVD device.

8. The manufacturing device of claim 6, wherein
the sub-line comprises:
a seventh rotation chamber;
an eighth rotation chamber;
a ninth rotation chamber connected to the first CVD device;
a tenth rotation chamber connected to the dry etching device;
an eleventh rotation chamber connected to the second CVD device;
a twelfth rotation chamber;
a fifth conveyance chamber which connects the seventh rotation chamber and the eighth rotation chamber to each other;
a sixth conveyance chamber which connects the eighth rotation chamber and the ninth rotation chamber to each other;
a seventh conveyance chamber which connects the ninth rotation chamber and the tenth rotation chamber to each other;
an eighth conveyance chamber which connects the tenth rotation chamber and the eleventh rotation chamber to each other;
a ninth conveyance chamber which connects the eleventh rotation chamber and the twelfth rotation chamber to each other;
a tenth conveyance chamber which connects the first rotation chamber and the seventh rotation chamber to each other;
an eleventh conveyance chamber which connects the second rotation chamber and the eighth rotation chamber to each other; and
a twelfth rotation chamber which connects the sixth rotation chamber and the twelfth rotation chamber to each other.

9. The manufacturing device of claim 1, wherein
the first evaporation device comprises:
first to seventh evaporation chambers for forming a hole injection layer, a hole transport layer, an electron blocking layer, a light emitting layer, a hole blocking layer, an electron transport layer and an electron injection layer, respectively, as the organic layer;
an eighth evaporation chamber for forming the upper electrode; and
ninth and tenth evaporation chambers for forming a first transparent layer and a second transparent layer, respectively, as the cap layer.

10. The manufacturing device of claim 1, wherein
the first evaporation device comprises:
first to ninth evaporation chambers for forming a hole injection layer, a hole transport layer, an electron blocking layer, a first light emitting layer, a second light emitting layer, a third light emitting layer, a hole blocking layer, an electron transport layer and an electron injection layer, respectively, as the organic layer;
a tenth evaporation chamber for forming the upper electrode; and
eleventh and twelfth evaporation chambers for forming a first transparent layer and a second transparent layer, respectively, as the cap layer, and
the fourth evaporation chamber, the fifth evaporation chamber and the sixth evaporation chamber comprise evaporation sources which emit light emitting materials which are different from each other.

11. The manufacturing device of claim 8, wherein
the first CVD devices are connected to the ninth rotation chamber,
the dry etching devices are connected to a tenth rotation chamber, and
the second CVD devices are connected to an eleventh rotation chamber.

12. The manufacturing device of claim 8, wherein
the main manufacturing line further comprises a thirteenth rotation chamber in a middle portion of the first evaporation device, and
the sub-line is connected to the thirteenth rotation chamber.
